(19) United States
(12) Patent Application Publication
(10) Pub. No.: US 2024/0324108 A1
(43) Pub. Date: Sep. 26, 2024

(54) ARCHITECTURES AND METHODS THAT ENABLE A REWORKABLE HEAT MANAGEMENT COMPONENT

(71) Applicant: Intel Corporation, Santa Clara, CA (US)

(72) Inventor: Juha T. Paavola, Hillsboro, OR (US)

(73) Assignee: Intel Corporation, Santa Clara, CA (US)

(21) Appl. No.: 18/188,297

(22) Filed: Mar. 22, 2023

(51) Int. Cl. H05K 3/30; H05K 1/02; H05K 1/16; H05K 1/18

(52) U.S. Cl. CPC H05K 3/301; H05K 1/0203; H05K 1/16; H05K 1/181

(57) ABSTRACT

Architectures and methods for a reworkable heat management component. A “debonding film” is deposited in cooperation with an adhesive to provide reworkable (“peelable”) heat management solutions for a variety of heat management components and IC components.

### BACKGROUND

Many low-power applications are migrating to architecture in which a heat management component is bonded to an integrated circuit (IC) component. The heat management solution can be bonded or attached to a surface of the IC component using an adhesive that has a low thermal resistance. In practice, many bonding methods are practically permanent, making rework (removing and replacing the heat management component) technically challenging, if not impossible. Accordingly, since there are scenarios in which it is desirable to rework the heat management component, technological improvements in this area are desirable.

### BRIEF DESCRIPTION OF THE DRAWINGS

FIG. 1A-1B are simplified views of a multi-die assembly, in accordance with disclosures defined herein.

FIGS. 2A-2C are simplified top-down views for discussion of a location for depositing a debonding film, in accordance with disclosures defined herein.

FIG. 3A is a simplified view showing a deposited debonding film, in accordance with various aspects of the present disclosure.

FIG. 3B is a simplified view showing an adhesive layer overlaid on the debonding film and a heat management solution attached thereto, in accordance with various aspects of the present disclosure.

FIG. 3C is a simplified view based on FIG. 3B, additionally depicting a standoff and fastening means, in accordance with various aspects of the present disclosure.

FIG. 4 is an exemplary process flow for fabrication of aspects of the present disclosure defined herein.

FIG. 5 is a top view of a wafer and dies that may embody integrated circuit components, in accordance with any of the aspects of the present disclosure disclosed herein.

FIG. 6 is a simplified cross-sectional side view showing an implementation of an integrated circuit component on a die that may be included in any of the aspects of the present disclosure disclosed herein.

FIG. 7 is a cross-sectional side view of a microelectronic assembly that may include any of the aspects of the present disclosure disclosed herein.

FIG. 8 is a block diagram of an example electrical device that may include any of the aspects of the present disclosure disclosed herein.

### DETAILED DESCRIPTION

Heat management components are often used to remove and reroute the heat generated during operation of an IC component. Examples of heat management components include cold plates, vapor chambers, heat pipes, a heat pipe soldered to a cold plate, and the like. Many low-power products attach or bond the heat management component directly to a surface of the IC component. Bonding the heat management component to the IC component enables a lower cost solution that is generally not reliant upon any through-holes in the printed circuit board (PCB) or dedicated surface mount technology (SMT, e.g., stand-offs).

An adhesive is generally used as a means for attachment to bond the heat management component to the IC component. To promote heat transfer, the adhesive is selected to be thermally conductive (alternatively, to have a low thermal resistance). However, once cured, many thermally conductive adhesives are practically permanent; in other words, it can be difficult or impossible to remove or peel away the heat transfer component from the IC component after the adhesive has cured. Additionally, removing a bonded heat management component introduces a risk of cracking solder joints of the IC component, such as, those functioning to attach the IC component to a PCB.

In some scenarios, such as, a cracked or improperly functioning heat management component, the heat management component needs to be removed and replaced (“reworked”), presenting a technical problem. When the adhesive does not permit a rework, the combined heat management component plus IC component may have to be discarded; this solution can be costly. In other solutions, such as when product thickness is not as much of an issue, a thermally compromised adhesive that is less thermally conductive (i.e., more thermally resistive) may be used, and an optional “locator wing” may be implemented to improve the security of the contact between the thermal management component and the IC that is being heat managed.

Aspects of the present disclosure provide a technical solution to this technical problem and other related enhancements, in the form of architectures and methods that enable a reworkable heat management component. Aspects of the present disclosure implement a “debonding film” (described in more detail below) that effectively blocks adhesion of an adhesive, to enable peeling off or reworking of heat management solutions for a variety of heat management components and IC components, as compared to available heat management solutions.

The provided aspects of the present disclosure can be detected with a visual inspection of the top surface of the IC die (i.e., the surface to which the heat management component was attached). A more detailed description of the aspects of the present disclosure follows a terminology section.

### Terminology

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary by plus or minus 20%(inclusive) from the meaning of the unmodified term or value. Terms or values modified by the word “about” include values inclusive of 10% less than the term or value to inclusive of 10% greater than the term or value.

As used herein, the terms “processor unit”, “processing unit” or “processor” may refer to any device or portion of a device that processes electronic data from registers and/or memory to transform that electronic data into other electronic data that may be stored in registers and/or memory. A processor unit may be a system-on-a-chip (SOC), and/or include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

As used herein, the term “electronic component” can refer to an active electronic circuit (e.g., a processing unit, a memory, a storage device, a field effect transistor (FET)) or a passive electronic component (e.g., resistor, inductor, capacitor).

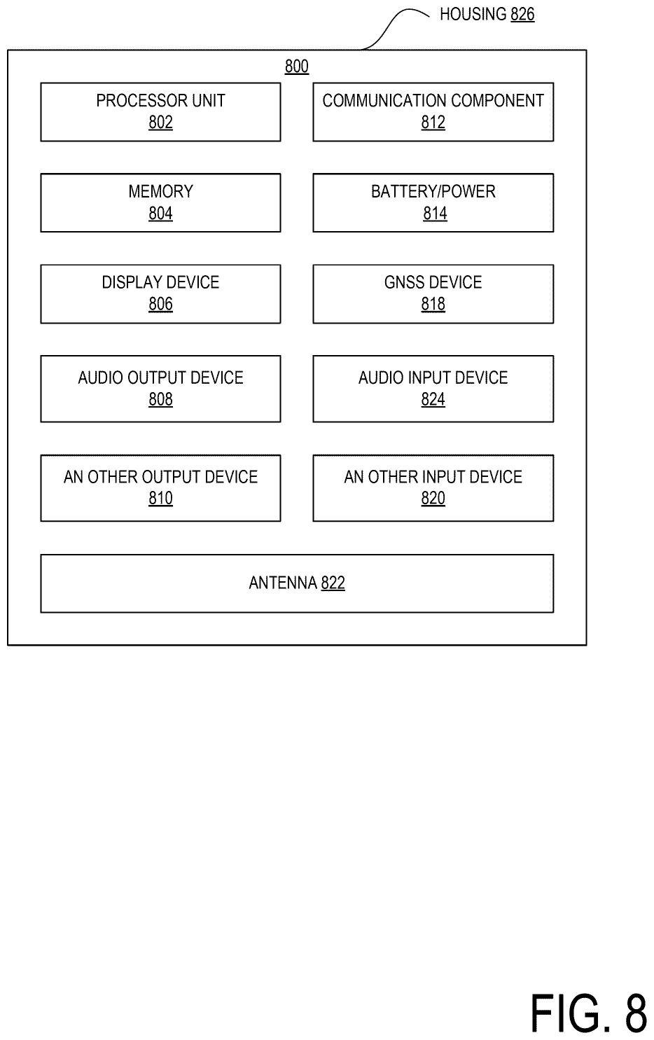

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (see, e.g., FIG. 8 discussion for processor unit 802 definition), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS) component; the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

### Description of Aspects of the Present Disclosure

Example aspects of the present disclosure are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import. For the sake of brevity, well-known structures and devices may be shown in block diagram form to facilitate a description thereof.

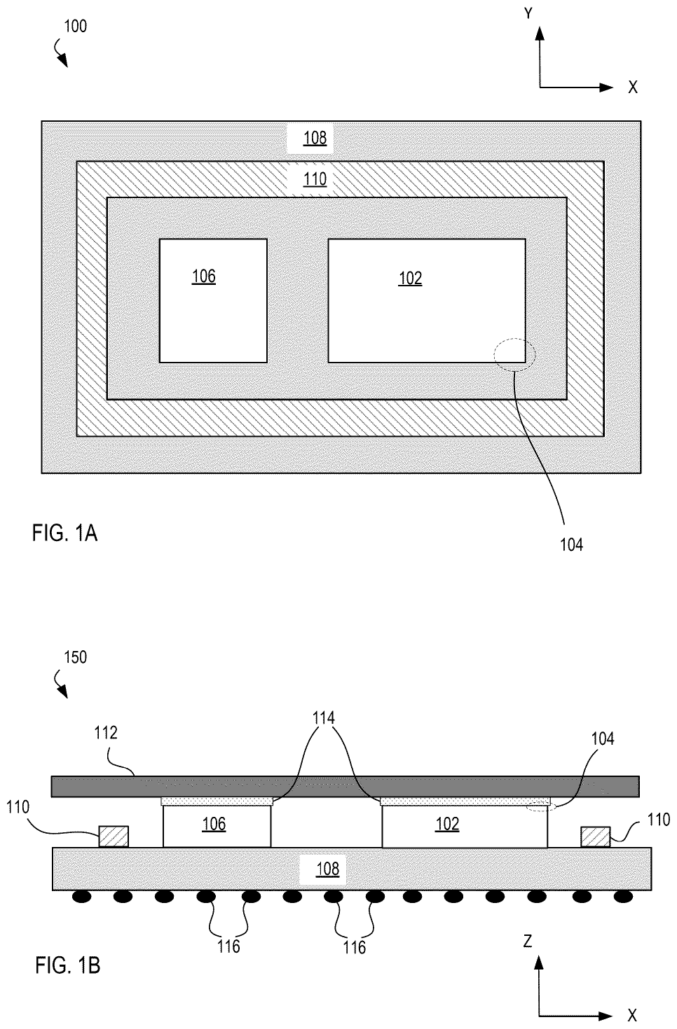

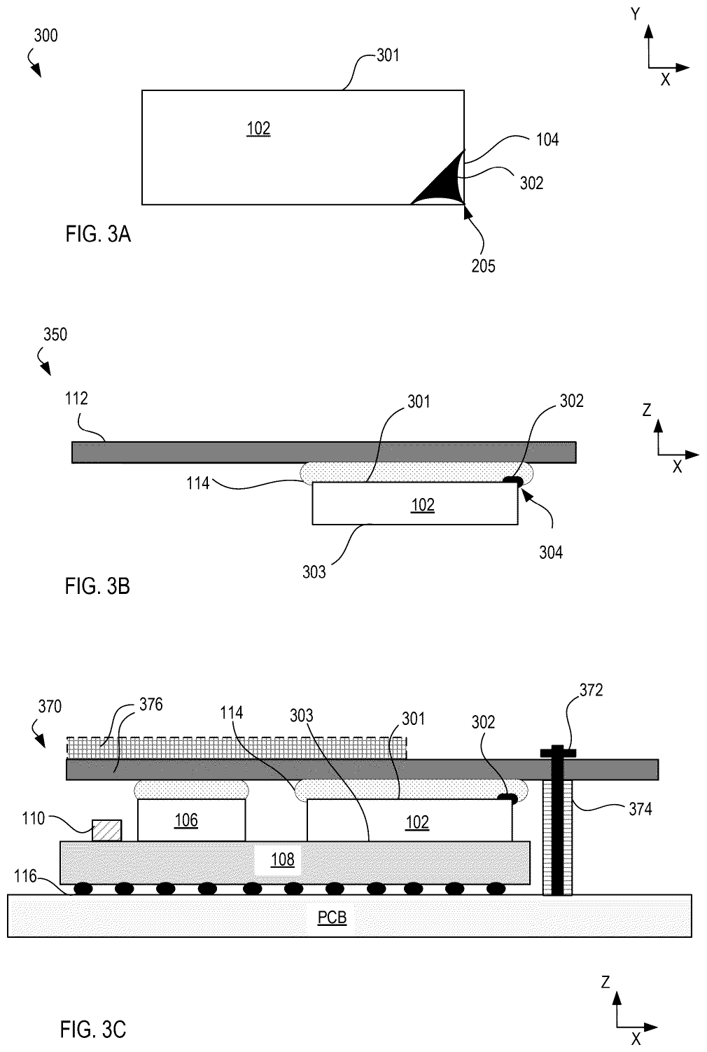

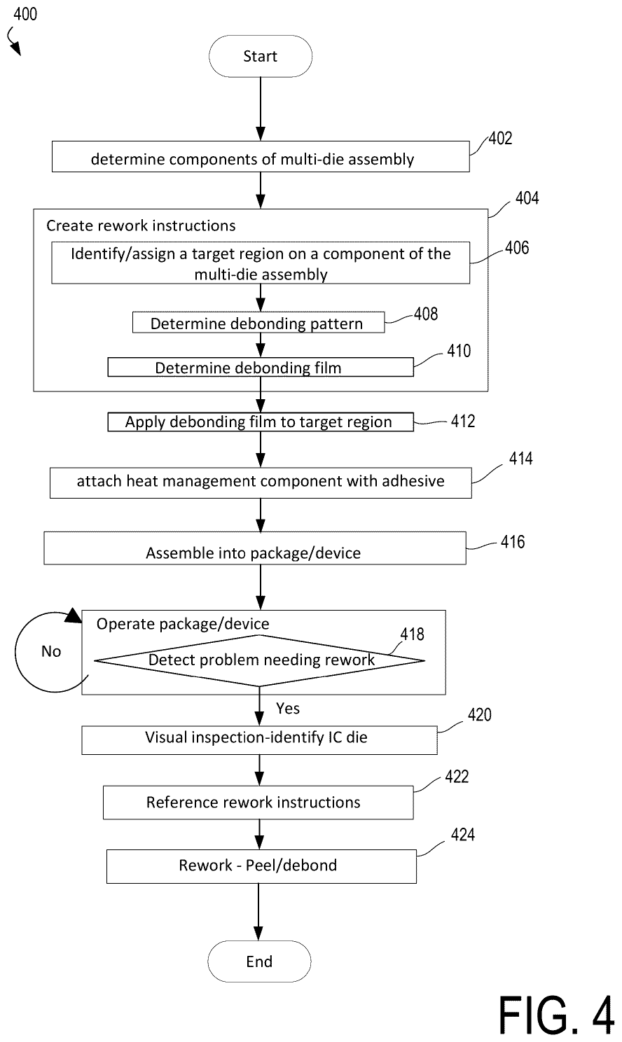

FIG. 1A is a simplified top-down view of a multi-die assembly 100 comprising two integrated circuit (IC) die: a first IC die 102 and a second IC die 106. The first IC die 102 and second IC die 106 have a top surface (FIG. 3, 301) and a bottom surface (FIG. 3, 303). The IC die are attached (e.g., via solder bumps, not shown) on their bottom surfaces to an upper surface of a substrate 108 layer, as shown. The apparatus of multi-die assembly 100 may be fabricated in accordance with a method 400, illustrated in FIG. 4.

FIG. 1B is a simplified side view 150 of multi-die assembly 100, with a heat management component 112 attached. The heat management component 112 may be attached via an adhesive 114 layer to the top surface of the IC die 102 and top surface of the IC die 106. A stiffener 110 component or standoff component may be used to support the substrate 108. In various aspects of the present disclosure, the stiffener 110 component may have a height (in the Z direction in the figure) of substantially 100 microns. In the illustration of FIG. 1A, the stiffener 110 substantially encircles the first IC die 102 and second IC die 106, and has a regular rectangular shape. In FIG. 1B, the stiffener 110 component is shown cut-away in a central region to make viewing the location of the IC die 102 and IC die 106 easier. In practice the stiffener 110 component may not fully enclose the IC die that comprise the multi-die assembly 100, the stiffener 110 may have an irregular shape, and its width may vary (e.g., 200 microns plus or minus 20%) as one traces it around its circumference (i.e., in the Y-X plane).

The IC die that comprise the multi-die assembly 100 may be different IC die selected to cooperate to perform an overall function. In a non-limiting example shown in embodiment 150, the multi-die assembly may be a “processor package,” in which the first IC die 102 performs a platform controller function and the second IC die 106 performs a processor unit function. The illustrated solder bumps 116 facilitate bidirectional electrical communication between the processor package and a printed circuit board (PCB), and may be part of a ball grid array (BGA). Once the components of the multi-die assembly 100 are determined (at 402), rework instructions may be created for the multi-die assembly at 404.

Rework instructions at 404 may comprise tasks 406, 408 and 410, as follows. At 406, the method 400 identifies one of the individual IC die of the multi-die assembly 100 to enable rework, and further selects a target of the IC die. For this example, the IC die 102 is selected to enable rework. The top surface of IC die 102 has an area. A target region 104 of the area is determined at 406. In various aspects of the present disclosure, the target region 104 is selected or determined for being a low power location. For this purpose, “low power” may mean more than 20% lower than a maximum operational power of the respective IC die. As those with skill in the art will appreciate, during operation, the power consumption and heat generated by the IC die is likely to vary, so there can be an arbitrariness to this designation. The target region 104 is smaller than the area and located on an edge of the top surface area (further, the target region 104 is located at a corner of the IC die 102, as illustrated). In some aspects of the present disclosure, the target region comprises substantially 0.1% of the area. In other embodiments, the target region is in a range of substantially 0.1% and substantially 5% of the area.

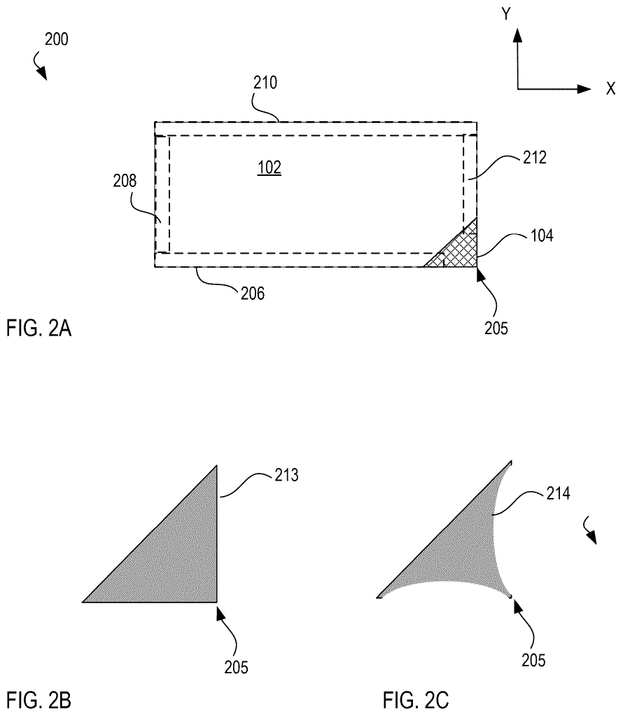

In various aspects of the present disclosure, the target region 104 is identified as a substantially triangular area, located substantially in a corner of the area (the top surface area of the IC die 102), as shown in embodiment 200 FIG. 2A; however, in other aspects of the present disclosure, the target region 104 may optionally include a leg extending along a top edge of the IC die, the leg having a width substantially between 0.1 millimeter and 1 millimeter (see, e.g., leg 206, leg 208, leg 210, and leg 212) of the top surface area of the IC die 102.

The target region will be overlaid with the debonding film in accordance with a selected pattern. A debonding pattern for the debonding film is selected at 408. In various aspects of the present disclosure, the debonding pattern 213 is substantially triangular, as shown in FIG. 2B. In some aspects of the present disclosure, the debonding pattern 214 is substantially triangular, but includes scalloped edges, as shown in FIG. 2C. The depicted debonding patterns 213 and 214 are just two non-limiting examples; other patterns may be implemented as well. A corner 205 of the debonding pattern may be substantially coincident with a corner of the IC die 102, as illustrated; this location can be a starting point for a subsequent peeling-off.

A suitable debonding film is selected at 410. Debonding film is selected to prevent the adhesive layer 114 from forming a strong hold on the underlying IC die 102, and to otherwise not interfere with the operation of the underlying IC die or the intended operation of the multi-die assembly 100 as a whole. In an aspect, the debonding film may be polytetrafluoroethylene (PTFE), a strong, tough, waxy, nonflammable synthetic resin produced by the polymerization of tetrafluoroethylene. PTFE is known by such trademarks as: Teflon™, Fluon™. Hostaflon™, and Polyflon™. PTFE is distinguished by its slippery surface, high melting point, and resistance to attack by almost all chemicals.

In various other aspects of the present disclosure, the debonding film may be a soap, a grease, a wax, an oil, a tape, or the like. As used herein, a soap or grease may include a mixture of the sodium salts of various fatty acids of natural oils and fats, or a metallic salt of a fatty acid, as of aluminum or iron, that is not water soluble and may be used as a lubricant. As used herein, a grease may consist of hydrocarbons or esters of fatty acids that are insoluble in water but soluble in nonpolar organic solvents.

Turning now to FIG. 3A, at 412, the selected debonding film 302 is applied in the target region 104 (adjacent to the top surface 301 of the IC die 102, as shown in 300). This is performed in accordance with the rework instructions of 404. In other words, the debonding film 302 is located on, and adjacent to, the top surface 301. The debonding film 302 is confined to substantially the target region 104.

At 414, a heat management component 112 is attached to the top surface 301 of the IC die 102, via an adhesive layer 114, as shown in embodiment 350, FIG. 3B At 414, in a first variation, various aspects of the present disclosure place (e.g., overlay) an adhesive layer 114 over the top surface of the IC die 102 to attach the heat management component 112 (which implies placing the adhesive layer 414 over the debonding film 302, as well as over locations of the top surface 301 not having the debonding film 302) and then place the heat management component 112 on the adhesive layer 114.

In another variation, at 414, separately, perhaps at a separate facility, the heat management component 112 has an adhesive layer 114 overlaid on a lower surface, to prepare for attaching it to the multi-die assembly 100, and then the combined heat management component 112 plus adhesive layer 114 is attached to the top surface of the IC die 102.

After 414, notably, the debonding film 302 prevents or occludes the adhesive layer 114 from forming a strong hold on the IC die 102, even when the adhesive layer 114 is squeezed out/over the periphery of the IC die 102, as illustrated with arrow 304.

In various aspects of the present disclosure, the heat management component 112 comprises one or more of a cold plate, a heat pipe, a heat pipe soldered to a cold plate, and a vapor chamber. As used herein, a cold plate, a heat pipe, and a vapor chamber have the meaning used by persons with skill in the art.

Although the substrate layer 108 was omitted in 350 for simplicity, the IC die 102 may be attached (at a lower surface 303) to the substrate layer 108 (see, e.g., FIG. 1B, FIG. 3C). In various aspects of the present disclosure, the substrate 108 layer comprises a printed circuit board (PCB) operationally attached to the lower surface 303. In other aspects of the present disclosure, as illustrated in FIG. 3C, the substrate 108 layer is attached to a PCB.

In 370, an optional fastener means 372 is illustrated. The optional fastener means 372 may be located (in the Y-X plane) near the debonding film 302 on the IC die 102 (alternatively, it can be described as being located near the target area 104) to secure the debonding film 302 from peeling off during operational usage (e.g., from shock or vibration loading). This optional fastener means 372 may have a lever/screw handle positioned on an upper surface of the heat management component 376, as shown. The optional fastener means 372 may extend downward through a standoff 374. The standoff 374 may be secured on a first end to the PCB, or any mechanical part (such as chassis) of a device or product. The standoff 374 may be sized such that a second end of the standoff 374 physically contacts a lower surface of the heat management component 376, as shown.

In various aspects of the present disclosure, the fastener means 372 may take the form of a screw, a wingnut on a threaded core, a solder plug, or the like. Embodiment 370 additionally depicts the heat management component 376 with an optional portion (in dashed lines and hatched) to represent a heat pipe, as may be attached at a terminal end to a heat exchanger (not illustrated).

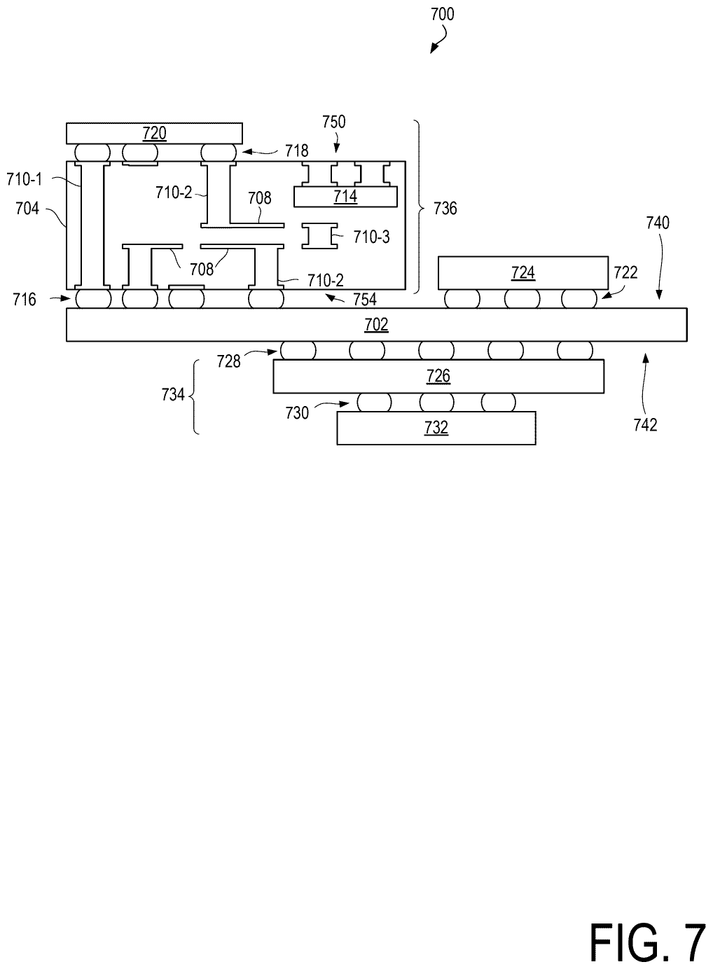

At 416, the multi-die assembly may be assembled into a packaged microelectronic assembly (e.g., 700, FIG. 7), or device (e.g., device 800 FIG. 8) or product. After assembly, the device, package or apparatus may be placed into operation. The process may pick back up at 418 if a problem needing rework is detected. At 420, if a problem needing rework is detected, a visual inspection may be performed to identify the multi-die assembly, and its component ICs. Respective rework instructions may be referenced at 422 for the multi-die assembly 100. The rework instructions inform a repair person where the target region 104 is located, which is where to begin to peel the heat management component 112 from the underlying IC die 102. Advantageously, at 424, by starting a peel at the target region 104, the heat management component 112 may be peeled off using a finger or a basic tool.

Thus, architectures and methods for a reworkable heat management component have been described, aspects of the present disclosure implement a “debonding film” to provide reworkable (“peelable”) heat management solutions for a variety of heat management components and IC components, as compared to available heat management solutions. The following description illustrates context for usage and application of provided aspects of the present disclosure.

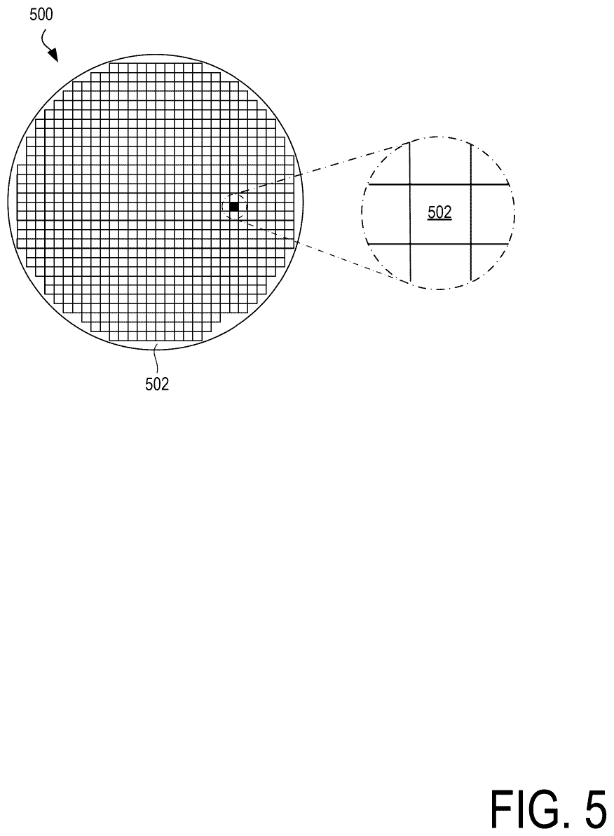

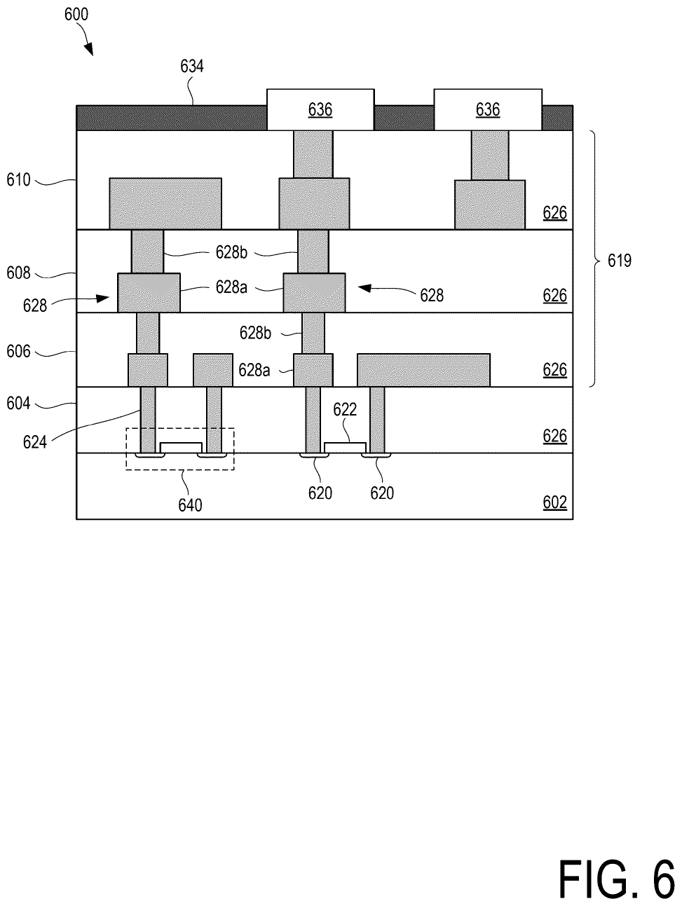

FIG. 5 is a top view of a wafer 500 and dies 502 that may embody integrated circuit components, in accordance with any of the aspects of the present disclosure disclosed herein. The wafer 500 may be composed of semiconductor material and may include one or more die 502 having integrated circuit structures formed on a surface of the wafer 500. The individual circuit structures on the die 502 may embody/implement an integrated circuit product or semiconductor product. After the fabrication of the semiconductor product is complete, the wafer 500 may undergo a singulation process in which the die 502 are separated from one another to provide discrete “chips” of the integrated circuit product. Respective die 502 may be any of the die disclosed herein. The die 502 may include one or more transistors (e.g., transistors referred to above, and/or some of the transistors 640 of FIG. 6, discussed below), supporting circuitry to route electrical signals to the transistors, passive components (e.g., signal traces, resistors, capacitors, or inductors), and/or any other integrated circuit components.

In some aspects of the present disclosure, in addition to or in conjunction with the above description, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array. Various ones of the microelectronics assemblies 700 disclosed herein may be manufactured using a die-to-wafer assembly technique in which some dies are attached to a wafer 500 that include others of the dies 502, and the wafer 500 is subsequently singulated.

FIG. 6 is a cross-sectional side view of an integrated circuit component 600 implemented on a die that may be included in any of the that may embody integrated circuit components, in accordance with any of the aspects of the present disclosure disclosed herein. One or more of the integrated circuit components 600 may be included in one or more dies 502 (FIG. 5). The integrated circuit component 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some aspects of the present disclosure, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit component 600 may be used. The die substrate 602 may be part of a singulated die (e.g., the dies 502 of FIG. 5) or a wafer (e.g., the wafer 500 of FIG. 5).

The integrated circuit component 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Continuing with FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some aspects of the present disclosure s, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some aspects of the present disclosure s, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other aspects of the present disclosure s, at least one of the metal layers that form the gate electrode may simply be a planar layer that is substantially parallel to the top surface of the die substrate 602 and does not include sidewall portions substantially perpendicular to the top surface of the die substrate 602. In other aspects of the present disclosure s, the gate electrode may consist of a combination of U-shaped structures and planar, non-U-shaped structures. For example, the gate electrode may consist of one or more U-shaped metal layers formed atop one or more planar, non-U-shaped layers.

In some aspects of the present disclosure s, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some aspects of the present disclosure s, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some aspects of the present disclosure s, the epitaxially deposited silicon alloy may be doped in situ with dopants such as boron, arsenic, or phosphorous. In some aspects of the present disclosure s, the S/D regions 620 may be formed using one or more alternate semiconductor materials such as germanium or a group III-V material or alloy. In further aspects of the present disclosure s, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit component 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, aspects of the present disclosure of the present disclosure include integrated circuit components having more or fewer interconnect layers than depicted.

In some aspects of the present disclosure s, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page. The vias 628b may be arranged to route electrical signals in a direction of a plane that is substantially perpendicular to the surface of the die substrate 602 upon which the device layer 604 is formed. In some aspects of the present disclosure s, the vias 628b may electrically couple lines 628a of different interconnect layers 606-610 together.

The interconnect layers 606-610 may include a dielectric material 626 disposed between the interconnect structures 628, as shown in FIG. 6. In some aspects of the present disclosure s, dielectric material 626 disposed between the interconnect structures 628 in different ones of the interconnect layers 606-610 may have different compositions; in other aspects of the present disclosure s, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other aspects of the present disclosure s, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some aspects of the present disclosure s, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some aspects of the present disclosure s, the second interconnect layer 608 may include via 628b to couple the lines that are interconnect structures 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some aspects of the present disclosure s.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some aspects of the present disclosure s, the interconnect layers that are “higher up” in the metallization stack 619 in the integrated circuit component 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit component 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit component 600 with another component (e.g., a printed circuit board). The integrated circuit component 600 may include additional or alternate structures to route the electrical signals from the interconnect layers 606-610; for example, the conductive contacts 636 may include other analogous features (e.g., posts) that route the electrical signals to external components.

In some aspects of the present disclosure in which the integrated circuit component 600 is double-sided, the integrated circuit component 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit component 600 from the conductive contacts 636.

In other aspects of the present disclosure in which the integrated circuit component 600 is a double-sided, the integrated circuit component 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit component 600 from the conductive contacts 636. In some aspects of the present disclosure s, TSVs extending through the substrate can be used for routing power and ground signals from conductive contacts on the opposite side of the integrated circuit component 600 from the conductive contacts 636 to the transistors 640 and any other components integrated into the die of the integrated circuit component 600, and the metallization stack 619 can be used to route I/O signals from the conductive contacts 636 to transistors 640 and any other components integrated into the die of the integrated circuit component 600.

Multiple integrated circuit components 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some aspects of the present disclosure s, the conductive contacts can be fine-pitch solder bumps (microbumps).

FIG. 7 is a cross-sectional side view of a “package assembly” or microelectronics assembly 700 that may include an apparatus or structure disclosed herein. The microelectronics assembly 700 includes a number of components disposed on a circuit board 702 (which may be a motherboard, system board, mainboard, etc.). The microelectronics assembly 700 includes components disposed on a first face 740 of the circuit board 702 and an opposing second face 742 of the circuit board 702; generally, components may be disposed on one or both faces 740 and 742.

In some aspects of the present disclosure s, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other aspects of the present disclosure s, the circuit board 702 may be a non-PCB substrate. In some aspects of the present disclosure the circuit board 702 may be, for example PCB. The microelectronics assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 716 may serve as the coupling components illustrated or described for any of the substrate assembly or substrate assembly components described herein, as appropriate.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit component 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some aspects of the present disclosure s, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In aspects of the present disclosure where the integrated circuit component 720 comprises multiple integrated circuit die, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In aspects of the present disclosure where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the aspects of the present disclosure illustrated in FIG. 7, the integrated circuit component 720 and the circuit board 702 are attached to opposing sides of the interposer 704; in other aspects of the present disclosure s, the integrated circuit component 720 and the circuit board 702 may be attached to a same side of the interposer 704. In some aspects of the present disclosure s, three or more components may be interconnected by way of the interposer 704.

In some aspects of the present disclosure s, the interposer 704 may be formed as a PCB, including multiple metal layers separated from one another by layers of dielectric material and interconnected by electrically conductive vias. In some aspects of the present disclosure s, the interposer 704 may be formed of an epoxy resin, a fiberglass-reinforced epoxy resin, an epoxy resin with inorganic fillers, a ceramic material, or a polymer material such as polyimide. In some aspects of the present disclosure s, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some aspects of the present disclosure s, the interposer 704 can comprise a silicon interposer. Through silicon vias (TSV) extending through the silicon interposer can connect connections on a first face of a silicon interposer to an opposing second face of the silicon interposer. In some aspects of the present disclosure s, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In aspects of the present disclosure where the interposer is a non-printed circuit board

The microelectronics assembly 700 may include an integrated circuit component 724 coupled to the first face 740 of the circuit board 702 by coupling components 722. The coupling components 722 may take the form of any of the aspects of the present disclosure discussed above with reference to the coupling components 716, and the integrated circuit component 724 may take the form of any of the aspects of the present disclosure discussed above with reference to the integrated circuit component 720.

The microelectronics assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the aspects of the present disclosure of the coupling components 716 discussed above, and the integrated circuit components 726 and 732 may take the form of any of the aspects of the present disclosure of the integrated circuit component 720 discussed above. The package-on-package structure 734 may be configured in accordance with any of the package-on-package structures known in the art.

FIG. 8 is a block diagram of an example electrical device 800 that may include an apparatus and/or structure disclosed herein. For example, any suitable ones of the components of the electrical device 800 may include one or more of the apparatus (e.g., 100, 130, 140), structures (e.g., 208, 214, 216), microelectronic assemblies 700, integrated circuit components, or integrated circuit dies 502 disclosed herein. A number of components are illustrated in FIG. 8 as included in the electrical device 800, but any one or more of these components may be omitted or duplicated, as suitable for the application. In some aspects of the present disclosure s, some or all of the components included in the electrical device 800 may be attached to one or more motherboards mainboards, or system boards. In some aspects of the present disclosure s, one or more of these components are fabricated onto a single system-on-a-chip (SoC) die. In some aspects of the present disclosure s, some or all of the components included in the electrical device 800 may be enclosed in a housing 826.

Additionally, in various aspects of the present disclosure s, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802, as defined herein. The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some aspects of the present disclosure s, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some aspects of the present disclosure s, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some aspects of the present disclosure s, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some aspects of the present disclosure they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other aspects of the present disclosure s. The electrical device 800 may include an antenna 822 to facilitate wireless communications and/or to receive other wireless communications (such as AM or FM radio transmissions).

In some aspects of the present disclosure s, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as Global positioning system (GPS), EDGE, GPRS, CDMA, WiMAX, LTE, EV-DO, or others. In some aspects of the present disclosure s, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an Ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some aspects of the present disclosure s, the electrical device 800 may be any other electronic device that processes data. In some aspects of the present disclosure s, the electrical device 800 may comprise multiple discrete physical components. Given the range of devices that the electrical device 800 can be manifested as in various aspects of the present disclosure s, in some aspects of the present disclosure s, the electrical device 800 can be referred to as a computing device or a computing system.

While at least one aspects of the present disclosure has been presented in the foregoing detailed description, it should be appreciated that a vast number of variations exist. It should also be appreciated that the disclosed aspects of the present disclosure are only examples, and are not intended to limit the scope, applicability, or configuration of the disclosure in any way. Rather, the foregoing detailed description will provide those skilled in the art with a convenient road map for implementing the disclosed aspects of the present disclosure. Various changes can be made in the function and arrangement of elements without departing from the scope of the disclosure as set forth in the appended claims and the legal equivalents thereof.

Additionally, theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

As used herein, phrases such as “an aspect of the present disclosure,” “various aspects of the present disclosure,” “some aspects of the present disclosure,” and the like, indicate that some aspects of the present disclosure may have some, all, or none of the features described for other aspects of the present disclosure. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” can mean any combination of the listed terms. For example, the phrase “at least one of A, B and C” can mean A; B; C; A and B; A and C; B and C; or A, B, and C. Similarly, as used in this application and the claims, a list of items joined by the term “one or more of” can mean any combination of the listed terms. For example, the phrase “one or more of A, B and C” can mean A; B; C; A and B; A and C; B and C; or A, B, and C.

The following Examples pertain to additional aspects of the present disclosure of technologies disclosed herein.

Example 1 is an apparatus, comprising: a substrate layer having an upper surface and a lower surface; an integrated circuit (IC) die having a top surface and a bottom surface, the top surface having an area, the area comprising a target region that is smaller than the area and located on an edge of the area, the bottom surface attached to the upper surface of the substrate layer; and a debonding film located adjacent to the top surface of the IC die and confined to substantially the target region of the area.

Example 2 includes the subject matter of Example 1, further comprising a heat management component attached to the top surface via an adhesive layer.

Example 3 includes the subject matter of Example 1 of Example 2, wherein the target region is in a range of substantially 0.1% and substantially 5% of the area.

Example 4 includes the subject matter of any one of Examples 1-3, wherein the target region comprises scalloped edges.

Example 5 includes the subject matter of any one of Examples 1-4, wherein the target region includes a leg extending along a top edge of the IC die, the leg having a width substantially between 0.1 millimeter and 1 millimeter.

Example 6 includes the subject matter of any one of Examples 1-5, wherein the target region is associated with a low power area in the IC die.

Example 7 includes the subject matter of any one of Examples 1-6, wherein the debonding film comprises polytetrafluoroethylene.

Example 8 includes the subject matter of any one of Examples 1-6, wherein the debonding film comprises one or more of a soap, a grease, a wax, and an oil.

Example 9 includes the subject matter of any one of Examples 1-8, wherein the IC die is a platform controller die and further including a processor die attached on the upper surface of the substrate layer.

Example 10 includes the subject matter of any one of Examples 1-9, further comprising a stiffener component, the stiffener component located on the substrate layer.

Example 11 includes the subject matter of any one of Examples 1-10, wherein the substrate layer is a printed circuit board (PCB).

Example 12 includes the subject matter of any one of Examples 2-11, wherein the heat management component comprises a cold plate.

Example 13 includes the subject matter of any one of Examples 2-11, wherein the heat management component comprises one or more of a heat pipe, a heat pipe soldered to a cold plate, and a vapor chamber.

Example 14 includes the subject matter of any one of Examples 1-8, wherein the IC die comprises a graphics processing unit (GPU).

Example 15 includes the subject matter of any one of Examples 1-10, further comprising a printed circuit board operationally attached to the lower surface of the substrate layer.

Example 16 is a device, comprising the subject matter of any one of Examples 1-10, and further comprising: a printed circuit board (PCB) operationally attached to the lower surface of the substrate layer; a standoff positioned near the target region; and the standoff extends from the PCB at a first end to the heat management component at a second end.

Example 17 includes the subject matter of Example 16, further comprising a fastener means to adjustably secure the heat management component to the PCB.

Example 18 is a method comprising: building a multi-die assembly comprising an integrated circuit (IC) die attached to an upper surface of a substrate; creating rework instructions for the multi-die assembly, the rework instructions comprising: identifying a target region as a corner of a top surface of the IC die; determining a debonding film; determining a debonding pattern; and applying the debonding film adjacent to the target region, in accordance with the rework instructions.

Example 19 includes the subject matter of Example 18, further comprising attaching a heat management component to the top surface of the IC die via an adhesive layer.

Example 20 includes the subject matter of Example 19, further comprising: operating the multi-die assembly; detecting a functional problem during operation of multi-die assembly; referencing the rework instructions for the multi-die assembly; and debonding, starting from the target region, the heat management component from the top surface of the IC die.

What is claimed is:

1. An apparatus, comprising:
a substrate layer having an upper surface and a lower surface;
an integrated circuit (IC) die having a top surface and a bottom surface, the top surface having an area, the area comprising a target region that is smaller than the area and located on an edge of the area, the bottom surface attached to the upper surface of the substrate layer; and
a debonding film located adjacent to the top surface of the IC die and confined to the target region of the area.

2. The apparatus of claim 1, further comprising a heat management component attached to the top surface via an adhesive layer.

3. The apparatus of claim 1, wherein the target region is in a range of about 0.1% and about 5% of the area.

4. The apparatus of claim 1, wherein the target region comprises scalloped edges.

5. The apparatus of claim 1, wherein the target region includes a leg extending along a top edge of the IC die, the leg having a width between about 0.1 millimeter and about 1 millimeter.

6. The apparatus of claim 1, wherein the target region is associated with a low power area in the IC die.

7. The apparatus of claim 1, wherein the debonding film comprises polytetrafluoroethylene.

8. The apparatus of claim 1, wherein the debonding film comprises one or more of a soap, a grease, a wax, and an oil.

9. The apparatus of claim 1, wherein the IC die is a platform controller die and further including a processor die attached on the upper surface of the substrate layer.

10. The apparatus of claim 1, further comprising a stiffener component, the stiffener component located on the substrate layer.

11. The apparatus of claim 1, wherein the substrate layer is a printed circuit board (PCB).

12. The apparatus of claim 2, wherein the heat management component comprises a cold plate.

13. The apparatus of claim 2, wherein the heat management component comprises a heat pipe or a vapor chamber.

14. The apparatus of claim 1, wherein the IC die comprises a graphics processing unit (GPU).

15. The apparatus of claim 1, further comprising a printed circuit board operationally attached to the lower surface of the substrate layer.

16. A device, comprising the apparatus of claim 2, and further comprising:
a printed circuit board (PCB) operationally attached to the lower surface of the substrate layer;
a standoff positioned near the target region; and
the standoff extends from the PCB at a first end to the heat management component at a second end.

17. The device of claim 16, further comprising a fastener means to adjustably secure the heat management component to the PCB.

18. A method comprising:
building a multi-die assembly comprising an integrated circuit (IC) die attached to an upper surface of a substrate;
creating rework instructions for the multi-die assembly, the rework instructions comprising:
identifying a target region as a corner of a top surface of the IC die;
determining a debonding film;
determining a debonding pattern; and
applying the debonding film adjacent to the target region, in accordance with the rework instructions.

19. The method of claim 18, further comprising attaching a heat management component to the top surface of the IC die via an adhesive layer.

20. The method of claim 19, further comprising:
operating the multi-die assembly;
detecting a functional problem during operation of multi-die assembly;
referencing the rework instructions for the multi-die assembly; and
debonding, starting from the target region, the heat management component from the top surface of the IC die.
